(19) United States
(12) Patent Application Publication
(10) Pub. No.: US 2015/0372668 A1
(43) Pub. Date: Dec. 24, 2015

(54) COMPARATOR CONTROL CIRCUIT

(71) Applicant: Raydium Semiconductor Corporation, Hsinchu (TW)

(72) Inventor: Tzong-Yau KU, Hsinchu (TW)

(21) Appl. No.: 14/741,923

(22) Filed: Jun. 17, 2015

(30) Foreign Application Priority Data
Jun. 23, 2014 (TW) 103121628

(51) Int. Cl. H03K 5/24

(52) U.S. Cl. CPC H03K 5/2472

(57) ABSTRACT

A comparator control circuit includes a current source, a first input unit, a second input unit, switches, and a ground terminal. The current source generates an input current. The input current is divided into a first current flowing through the first input unit and a second current flowing through the second input unit. The first input unit receives a signal voltage. The second input unit receives a reference voltage. The first input unit and second input unit are coupled to the current source. The switches include a first switch and a second switch. The second switch has a control voltage. The ground terminal is coupled to the switches. When the first input unit is at high-level, the first switch is switched off and second switch is switched off by the control voltage to stop the second current flowing from the second input unit to the ground terminal.

### BACKGROUND OF THE INVENTION

1. Field of the Invention

This invention relates to a comparator control circuit, especially to a hysteresis comparator control circuit capable of saving power.

2. Description of the Related Art

In general, mobile industry processor interface (MIPI) is usually used as a transmission system of driving circuit in current small-size electronic apparatus. In practical applications, the MIPI can include a high-speed interface and a low-power interface. The operation frequency of the high-speed interface is about 1.2 GHz and the operation frequency of the low-power interface is about 10 MHz. The high-speed interface is used to transmit data; therefore, the high-speed interface of the MIPI can be shut down to reduce power consumption.

In addition, the low-power interface is used to transmit command and the command includes a setting value or other setting data. It should be noticed that the low-power interface of the MIPI receives command through a receiver; therefore, no matter the low-power interface receives command through the receiver or not, there will be current continuously passing by. In other words, it is hard to solve the power consumption problem of the MIPI. For example, in this condition, the power consumption of the entire circuit is about 50%. Especially, there is still no suitable solution to solve the power consumption problem when the receiver does not receive command.

For example, please refer to FIG. 1, FIG. 1 illustrates a schematic diagram of the hysteresis comparator control circuit used as a receiver in the MIPI of the prior art. As shown in FIG. 1, in the conventional hysteresis comparator control circuit 1, when a MIPI signal IN is larger than a reference voltage REF (increasing a hysteresis voltage), the output signal outputted by the output terminal K is at high-level; when a MIPI signal IN is smaller than the reference voltage REF (decreasing the hysteresis voltage), the output signal outputted by the output terminal K is at low-level. The hysteresis comparator control circuit 1 can generate the hysteresis voltage by adjusting a ratio of the size of a transistor MN2 (or MN3) to the size of a transistor MN1 (or MN4).

However, when the MIPI signal IN is at high-level, a bias current I will flow through the transistors MP1 and MN1 to a ground terminal GND; when the MIPI signal IN is at low-level, the bias current I will flow through the transistors MP2 and MN4 to a ground terminal GND; therefore, no matter the MIPI transmits the MIPI signal IN or not, constant power will be still continuously consumed, and the power consumption problem of the conventional hysteresis comparator control circuit 1 cannot be solved.

### SUMMARY OF THE INVENTION

Therefore, the invention provides a comparator control circuit to solve the above-mentioned problems.

A preferred embodiment of the invention is a comparator control circuit. In this embodiment, the comparator control circuit includes a current source, a first input unit, a second input unit, switches, and a ground terminal. The current source generates an input current. The input current is divided into a first current flowing through the first input unit and a second current flowing through the second input unit. The first input unit receives a signal voltage. The second input unit receives a reference voltage. The first input unit and second input unit are coupled to the current source. The switches include a first switch and a second switch. The second switch has a control voltage. The ground terminal is coupled to the switches. When the first input unit is at high-level, the first switch is switched off and second switch is switched off by the control voltage to stop the second current flowing from the second input unit to the ground terminal.

In an embodiment, the comparator control circuit includes a signal interface. The signal interface is coupled to the first input unit and used for transmitting the signal voltage to the first input unit, wherein the signal voltage drives the first input unit at high-level under a non-message transmitting state.

In an embodiment, the plurality of switches further includes a third switch, coupled between the first input unit and the ground terminal, wherein when the first input unit is at low-level, the first current flows to the ground terminal through the third switch.

In an embodiment, the comparator control circuit generates a hysteresis voltage according to a ratio of a current generated by the second switch to the input current, and a range of the hysteresis voltage has a hysteresis voltage upper limit and a hysteresis voltage lower limit.

In an embodiment, when the signal voltage is higher than the hysteresis voltage upper limit, the first input unit is at high-level.

In an embodiment, when the signal voltage is lower than the hysteresis voltage upper limit, the first input unit is at low-level.

In an embodiment, the range of the hysteresis voltage is between 400 mV and 1000 mV.

In an embodiment, the comparator control circuit further includes an output unit. The output unit is coupled to the plurality of switches and the ground terminal and used for generating a high output level or a low output level according to a relative relationship between the signal voltage and the reference voltage.

In an embodiment, the reference voltage ranges within the range of the hysteresis voltage.

In an embodiment, when the signal voltage is higher than the reference voltage, the output unit generates the high output level; when the signal voltage is lower than the reference voltage, the output unit generates the low output level.

The advantage and spirit of the invention may be understood by the following detailed descriptions together with the appended drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic diagram of the hysteresis comparator control circuit used as a receiver in the MIPI of the prior art.

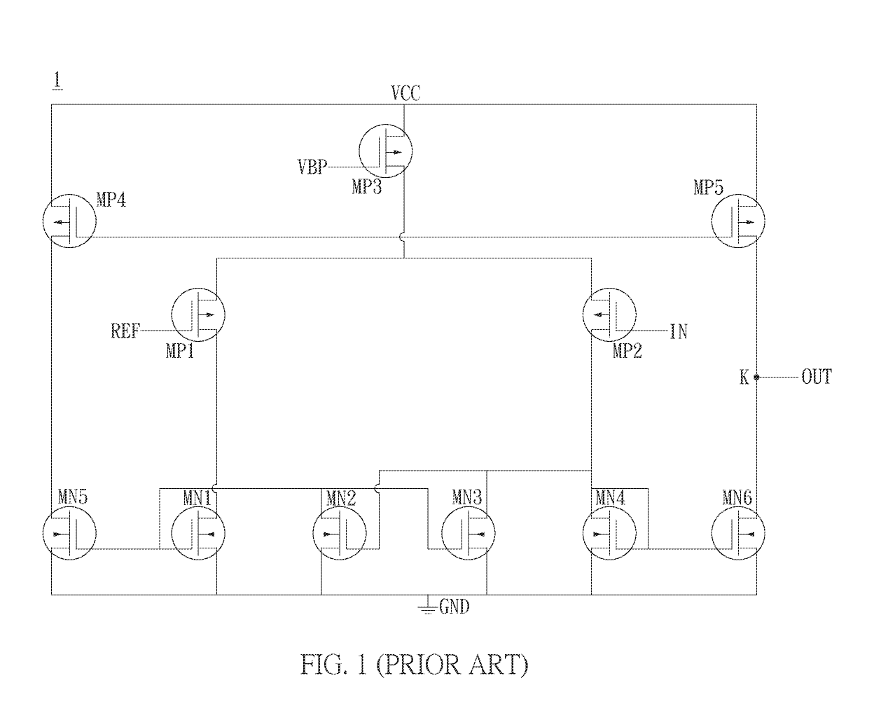

FIG. 2 illustrates a functional block diagram of the comparator control circuit according to an embodiment of the invention.

FIG. 3 illustrates a circuit diagram of the comparator control circuit according to an embodiment of the invention.

### DETAILED DESCRIPTION

A preferred embodiment of the invention is a comparator control circuit. In this embodiment, the comparator control circuit is a hysteresis comparator control circuit applied to a mobile industry processor interface (MIPI) to receive a MIPI signal and generate a hysteresis voltage.

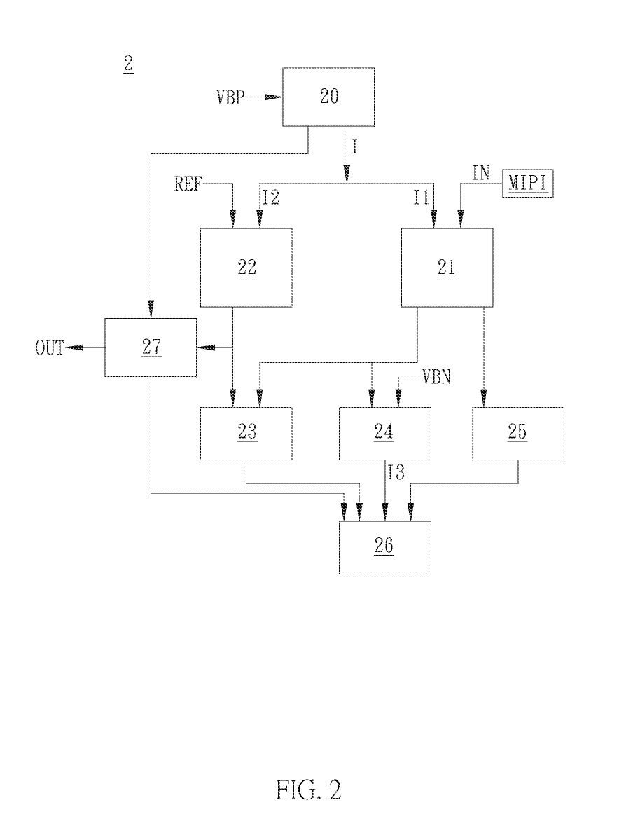

Please refer to FIG. 2. FIG. 2 illustrates a functional block diagram of the comparator control circuit in this embodiment. As shown in FIG. 2, the comparator control circuit 2 includes a current source 20, a first input unit 21, a second input unit 22, a plurality of switches 23-25, a ground terminal 26, an output unit 27, and a signal interface MIPI. The current source 20 is coupled to the first input unit 21, the second input unit 22, and the output unit 27; the first input unit 21 is coupled to the plurality of switches 23-25 and the signal interface MIPI respectively; the second input unit 22 is coupled to the switch 23 and the output unit 27 respectively; the plurality of switches 23-25 and the output unit 27 are coupled to the ground terminal 26.

In this embodiment, the current source 20 generates an input current I. The input current I is divided into a first current 11 flowing through the first input unit 21 and a second current 12 flowing through the second input unit 22.

The first input unit 21 receives a signal voltage IN from the signal interface MIPI. In fact, the signal interface MIPI can be a low power interface of the MIPI and its operation frequency is about 10 MHz, but not limited to this.

The signal voltage IN drives the first input unit 21 at high-level under a non-message transmitting state. The second input unit 22 receives a reference voltage REF. The second switch 24 has a control voltage VBN. When the first input unit 21 is at high-level, the first switch 23 is switched off and the second switch 24 is switched off by the control voltage VBN to stop the second current 12 flowing from the second input unit 22 to the ground terminal GND.

The third switch 25 is coupled between the first input unit 21 and the ground terminal GND. When the first input unit 21 is at low-level, the first current 11 flows to the ground terminal GND through the third switch 25.

It should be noticed that the comparator control circuit 2 generates a hysteresis voltage according to a ratio of a third current 13 generated by the second switch 24 to the input current I, and a range of the hysteresis voltage has a hysteresis voltage upper limit and a hysteresis voltage lower limit. In fact, the range of the hysteresis voltage is between 400 mV and 1000 mV, and the reference voltage REF received by the second input unit 22 ranges in the range of the hysteresis voltage, but not limited to this.

In this embodiment, when the signal voltage IN received by the first input unit 21 is higher than the hysteresis voltage upper limit, the first input unit 21 is at high-level. On the contrary, when the signal voltage IN received by the first input unit 21 is lower than the hysteresis voltage upper limit, the first input unit 21 is at low-level.

The output unit 27 generates a high output level or a low output level according to a relative relationship between the signal voltage IN and the reference voltage REF. In practical applications, when the signal voltage IN is higher than the reference voltage REF, the output unit 27 generates the high output level; when the signal voltage IN is lower than the reference voltage REF, the output unit 27 generates the low output level.

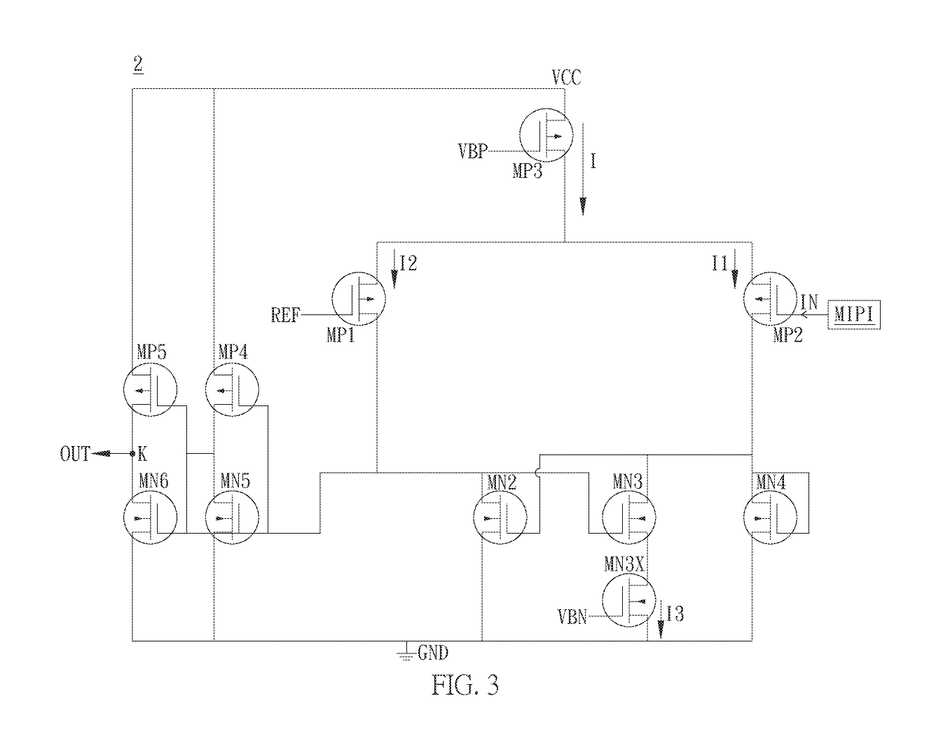

Please refer to FIG. 3. FIG. 3 illustrates a circuit diagram of the comparator control circuit 2 in an embodiment of the invention. As shown in FIG. 3, the comparator control circuit 2 includes a plurality of transistors MP1-MP5, MN2-MN6, MN3X, a signal interface MIPI, a ground terminal GND, and an output terminal K. Wherein, the transistors MP1-MP5 are P-type MOSFETs and the transistors MN2-MN6 and MN3X are N-type MOSFETs. The signal interface MIPI is a low power interface of the MIPI and its operation frequency is about 10 MHz.

One terminal of the transistor MP3 is coupled to the transistors MP2 and MP1 respectively, another terminal of the transistor MP3 is coupled to an operation voltage VCC, and a gate electrode of the transistor MP3 is coupled to a control voltage VBP; the transistor MP2 is coupled between the transistors MP3 and MN4 and a gate electrode of the transistor MP2 is coupled to the signal voltage IN inputted from the signal interface MIPI; One terminal of the transistor MP1 is coupled to the transistors MP2 and MP3 respectively, another terminal of the transistor MP1 is coupled to the transistors MN2, MN5, and MP4, and a gate electrode of the transistor MP1 is coupled to the reference voltage REF.

One terminal of the transistor MN2 is coupled to the transistors MP1, MN5, MP4, and MN3, and another terminal of the transistor MN2 is coupled to the ground terminal GND; one terminal of the transistor MN3 is coupled to the transistors MN2, MN4, and MP2, and another terminal of the transistor MN3 is coupled to the transistor MN3X; the transistor MN3X is coupled between the transistor MN3 and the ground terminal GND, and a gate electrode of the transistor MN3X is coupled to the control voltage VBN; one terminal of the transistor MN4 is coupled to the transistors MP2, MN2, and MN3, and another terminal of the transistor MN4 is coupled to the ground terminal GND.

The transistor MP4 is coupled between the operation voltage VCC and the transistor MN5, and a gate electrode of the transistor MP4 is coupled to the gate electrode of the transistor MN5, the transistors MN2 and MP1; the transistor MN5 is coupled between the transistor MP4 and the ground terminal GND, and a gate electrode of the transistor MN5 is coupled to the gate electrode of the transistor MP4 and the transistors MN2 and MP1; the transistor MP5 is coupled between the operation voltage VCC and the transistor MN6, and a gate electrode of the transistor MP5 is coupled to the gate electrode of the transistor MN6 and between the transistors MN5 and MP4; the transistor MN6 is coupled between the transistor MP5 and the ground terminal GND, and a gate of the transistor MN6 is coupled to the gate electrode of the transistor MP5 and between the transistors MN5 and MP4; an output terminal K is located between the transistors MP5 and MN6 to output an output signal OUT.

In the comparator control circuit 2, when the signal voltage IN is higher than the reference voltage REF (increasing the hysteresis voltage), the output signal OUT outputted by the output terminal K is at high-level; when the signal voltage IN is lower than the reference voltage REF (decreasing the hysteresis voltage), the output signal OUT outputted by the output terminal K is at low-level.

The comparator control circuit 2 generates the wanted hysteresis voltage by adjusting the ratio of the third current 13 and the input current I, wherein the third current 13 is generated by the transistor MN3X according to the control voltage VBN, and the input current I is generated by the transistor MP3 according to the control voltage VBP.

A range of the hysteresis voltage generated by the comparator control circuit 2 has a hysteresis voltage upper limit and a hysteresis voltage lower limit. In fact, the range of the hysteresis voltage can be a value between 400 mV and 1000 mV, and the reference voltage REF received by the second input unit 22 can range within the range of the hysteresis voltage, but not limited to this.

It should be noticed that, in the comparator control circuit 2, when the signal voltage IN is at low-level, the input current I generated by the transistor MP3 according to the control voltage VBP will flow through the transistors MP2 and MN4 to the ground terminal GND; therefore, constant power will be still consumed continuously.

Compared to the conventional comparator control circuit 1, the comparator control circuit 2 of the invention has no transistor MN1; therefore, when the signal voltage IN is at high-level, the input current I generated by the transistor MP3 according to the control voltage VBP will flow through the transistor MP1 and then the input current I cannot flow to the ground terminal GND through the transistor MN1, and there will be no constant power consumed continuously.

That is to say, under the condition that the signal interface MIPI transmits no signal voltage IN to the transistor MP2 (the first input unit 21 is at high-level), the power consumption of the comparator control circuit 2 is lower than that of the conventional comparator control circuit 1. Therefore, the power consumption problem of the conventional comparator control circuit 1 can be effectively improved.

Compared to the comparator control circuit 1 in the prior arts, since the comparator control circuit 2 of the invention has no transistor MN1, when the signal voltage IN inputted by the MIPI is at high-level, the input current I generated by the transistor MP3 according to the control voltage VBP will flow through the transistor MP1 and then the input current I cannot flow to the ground terminal GND through the transistor MN1, and there will be no constant power consumed continuously. Therefore, the power consumption problem when the receiver does not receive command in the prior arts can be effectively improved.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A comparator control circuit, comprising:
a current source generating an input current, wherein the input current is divided into a first current and a second current;
a first input unit receiving a signal voltage, wherein the first current flows through the first input unit;
a second input unit receiving a reference voltage, wherein the first input unit and the second input unit are coupled to the current source, and the second current flows through the second input unit;
a plurality of switches comprising a first switch and a second switch, wherein the second switch has a control voltage; and
a ground terminal coupled to the plurality of switches;
wherein when the first input unit is at high-level, the first switch is switched off, and the second switch is switched off by the control voltage to stop the second current flowing from the second input unit to the ground terminal.

2. The comparator control circuit of claim 1, further comprising:
a signal interface, coupled to the first input unit, for transmitting the signal voltage to the first input unit, wherein the signal voltage drives the first input unit at high-level under a non-message transmitting state.

3. The comparator control circuit of claim 1, wherein the plurality of switches further comprises:
a third switch, coupled between the first input unit and the ground terminal, wherein when the first input unit is at low-level, the first current flows to the ground terminal through the third switch.

4. The comparator control circuit of claim 3, wherein the comparator control circuit generates a hysteresis voltage according to a ratio of a current generated by the second switch to the input current, and a range of the hysteresis voltage has a hysteresis voltage upper limit and a hysteresis voltage lower limit.

5. The comparator control circuit of claim 4, wherein when the signal voltage is higher than the hysteresis voltage upper limit, the first input unit is at high-level.

6. The comparator control circuit of claim 4, wherein when the signal voltage is lower than the hysteresis voltage upper limit, the first input unit is at low-level.

7. The comparator control circuit of claim 4, wherein the range of the hysteresis voltage is between 400 mV and 1000 mV.

8. The comparator control circuit of claim 1, further comprising:
an output unit, coupled to the plurality of switches and the ground terminal, for generating a high output level or a low output level according to a relative relationship between the signal voltage and the reference voltage.

9. The comparator control circuit of claim 4, wherein the reference voltage ranges within the range of the hysteresis voltage.

10. The comparator control circuit of claim 8, wherein when the signal voltage is higher than the reference voltage, the output unit generates the high output level; when the signal voltage is lower than the reference voltage, the output unit generates the low output level.
